(19) United States
(12) Patent Application Publication
(10) Pub. No.: US 2006/0286799 A1
(43) Pub. Date: Dec. 21, 2006

(54) Electrode structure for flexible display device and method for forming the same

(75) Inventor: Young-Nam Lim, Anyang (KR)

Correspondence Address: BRINKS HOFER GILSON & LIONE, P.O. BOX 10395, CHICAGO, IL, 60610, US

(73) Assignee: LG PHILIPS LCD CO., LTD.

(21) Appl. No.: 11/454,579

(22) Filed: Jun. 15, 2006

(30) Foreign Application Priority Data
Jun. 16, 2005 (KR) 52076/2005

(51) Int. Cl. H01L 21/44

(52) U.S. Cl. 438/674

(57) ABSTRACT

A method for forming an electrode comprises forming a carbon nano tube of a gel state by mixing a carbon nano tube with an ionic liquid. The method for forming an electrode for a flexible display device further comprises printing the carbon nano tube of a gel state on a substrate.

This application claims the benefit of Korean Patent Application No. 52076/2005 filed in Korea on Jun. 16, 2005, which is hereby incorporated by reference.

### FIELD

The present invention relates to an electrode structure for a flexible display device and a method for forming the same, and more particularly, to an electrode structure for a flexible display device capable of being used at a flexible substrate and having a high conductivity by forming an electrode using a carbon nano tube dissolved in ionic liquid as a gel state, and a method for forming the same.

### BACKGROUND

Recently, a display device is being spotlighted as a medium for transmitting visual information in an information society. In order to occupy a major position in the future, the display device has to satisfy low power consumption, a thin and light characteristic, high picture quality, etc.

The display device is divided into a spontaneous luminescent type such as a cathode ray tube (CRT), an electrode luminescence (EL), a vacuum fluorescent display (VFD), a field emission display (FED), a plasma display panel (PDP), etc., and a non-spontaneous luminescent type such as a liquid crystal display (LCD).

A flexible display device which is not damaged even when folded will be spotlighted as a new display device. There are many obstacles in implementing the flexible display device at present. However, a thin film transistor (TFT), a liquid crystal display (LCD) device, an organic light emitting diode (OLED) device, and an electrophoresis device will be developed by many researches.

The flexible display device refers to a display device that can be easily bent. Since the flexible display device is constituted with a flexible substrate such as plastic, it is not damaged when folded like paper. The flexible display device refers to any flexible display device but not a specific display device. The flexible display device can be implemented as various display devices. Recently, an organic light emitting diode (OLED) device and a liquid crystal display (LCD) device that can be fabricated with a thickness less than 1 mm is being spotlighted.

Since the OLED device emits light spontaneously, it can be easily recognized even in a dark place or when external light is incident thereon. Also, since the OLED device has the shortest response time among the existing display devices, it can implement a perfect moving image. Furthermore, since the OLED device can be fabricated to be thin, each kind of mobile device such as a portable phone, etc. can be slim.

The LCD device serves to display an image by using an optical anisotropy of liquid crystal. Since the LCD device has more excellent visibility, less power consumption, and less heating value when compared with the conventional CRT, it is being spotlighted as a next generation display device.

In order to fabricate the flexible LCD or OLED device, a flexible substrate has to be used. Then, an electrode for applying an electric field to a liquid crystal layer or an organic luminescent layer, and a thin film transistor which is a switching device for applying a signal have to be formed on the substrate.

Generally, the electrode and the switching device are formed on the LCD device or the OLED device by a photolithography process. That is, a conductive metal is deposited by a sputtering process, and then is etched. However, the photolithography process includes a series of processes such as a metal layer forming process, a photoresist layer forming process, a developing process, an etching process, etc. As a result, fabrication processes are complicated and fabrication cost is increased. Furthermore, since the metal layer can not be bent, it can not be applied to a flexible display device.

### SUMMARY

A method for forming an electrode comprises forming a carbon nano tube of a gel state by mixing a carbon nano tube with an ionic liquid. The method for forming an electrode further comprises printing the carbon nano tube of a gel state on a substrate.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIGS. 1A and 1B are views showing a method for forming an electrode for a flexible display device according to a first embodiment of the present invention;

FIGS. 2A and 2B are views showing a method for forming an electrode for a flexible display device according to a second embodiment of the present invention; and

FIGS. 3A and 3B are views showing a method for forming an electrode for a flexible display device according to a third embodiment of the present invention.

### DETAILED DESCRIPTION

Reference will now be made in detail to the preferred embodiments of the present invention, examples of which are illustrated in the accompanying drawings.

The present invention provides an electrode structure for a flexible display device. In order to implement a conductive layer such as an electrode for a flexible display device, the electrode has to maintain a flexibility. That is, the electrode has to be conductive and have a softness. The conductive layer can be formed by using a conductive polymer which is a material having an excellent softness. Since the conductive polymer includes a polyimide component to form an alignment layer, it serves as both a conductive layer and an alignment layer. Therefore, when the conductive polymer is applied to a flexible LCD device, an entire structure can be simplified.

However, since the conductive polymer has a relatively smaller conductivity than a metal, it causes a signal delay in a display device when compared with a metal layer. Furthermore, the conductive polymer has an inferior molding characteristic due to a high viscosity, thereby causing a problem when used to form an electrode of a complicated structure.

In order to solve the problems of the conductive polymer, a carbon nano tube is used in the present invention. The carbon nano tube has a tube shape as hexagonal structures are connected to one another, each hexagonal structure is composed of 6 carbons, and has an excellent conductivity and intensity. However, when the carbon nano tube is mixed with the conventional polymer for use, the carbon nano tube has a high viscosity due to a massed state, thus has an inferior molding characteristic. Therefore, there was a problem in forming an electrode by only the carbon nano tube itself.

In the present invention, the carbon nano tube is mixed with an imidazolium-based ionic liquid thus to be in a gel state having a low viscosity, thereby forming an electrode of a desired pattern.

Generally, the ionic liquid is used as an eco-friendly solvent that can substitute the conventional organic solvent due to a vapor pressure corresponding to an approximately zero and due to no burning property or combustibility. Since the ionic liquid has a high polarity, it can be used to dissolve many organic compounds. The imidazolium-based ionic liquid of the present invention permeates into the carbon nano tube more deeply than a general ionic liquid when mixed with the carbon nano tube, thereby dissolving the carbon nano tube. As the result, the ionic liquid becomes a gel state having a low viscosity.

The carbon nano tube dissolved in the imidazolium-based ionic liquid has a more excellent conductivity than the conventional conductive polymer by approximately 100,000 times, and has an excellent molding characteristic due to a low viscosity. Especially, since the carbon nano tube of a gel state has a softness, it can be used to fabricate an electrode for a flexible display device. Furthermore, the carbon nano tube has a high intensity and durability, and is transparent since it is dissolved in the transparent imidazolium-based ionic liquid at a nano size.

In the present invention, as a substrate having an electrode structure by the carbon nano tube of a gel state, a plastic substrate having a light weight, a strong impact resistance, and a high portable characteristic due to a flexible characteristic is used. The plastic substrate is formed of a transparent material such as polyethylene-etherphthalate, polyethylene-naphthalate, polycarbonate, polyarylate, polyetherimide, polyethersulfone, and polyimide. Even if the plastic substrate has a transition temperature lower than that of glass, it is mainly used due to light and flexible characteristics.

Hereinafter, a method for forming an electrode structure for a flexible display device by using a carbon nano tube of a gel state will be explained with reference to the attached drawings.

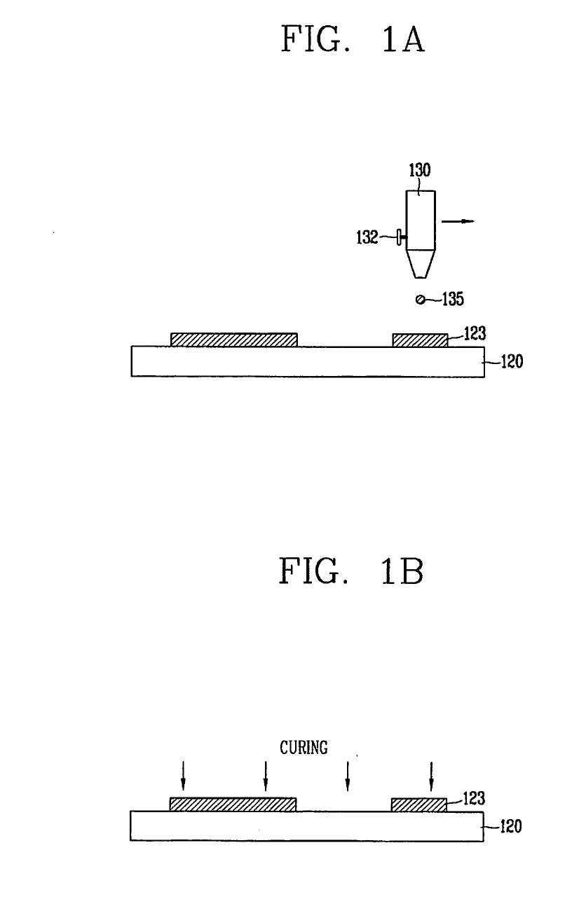

FIGS. 1A and 1B are views showing a method for forming an electrode for a flexible display device according to a first embodiment of the present invention, in which an ink jet printing method is used. As shown in FIG. 1A, a nozzle 130 having an opening of a certain size is aligned above a flexible substrate 120.

Although not shown, the nozzle 130 is connected to a supply means in which a carbon nano tube of a gel state 135 mixed with an imidazolium-based ionic liquid is filled, so that the carbon nano tube of a gel state is supplied into the nozzle 130.

The carbon nano tube 135 supplied to the nozzle 130 is discharged from the opening of the nozzle 130 thus to be deposited on the substrate 120. Herein, since the nozzle 130 is provided with a valve 132 for controlling a discharge amount of the carbon nano tube, a desired amount of carbon nano tube 135 can be deposited on the substrate 120. The nozzle 130 moves above the substrate 120 with a constant speed (v1), thereby uniformly depositing the carbon nano tube 135 on the substrate 120 and depositing the carbon nano tube 135 only on a desired position by controlling the valve 132.

The carbon nano tube 135 discharged from the nozzle 130 has a gel state and a certain mobility. As shown in FIG. 1B, the carbon nano tube 135 of a gel state deposited on the substrate has to be cured at a set temperature in order to form a firm electrode 123. The curing process is determined by a viscosity, a thickness, etc. of the carbon nano tube 135.

In the present invention, the carbon nano tube of a gel state dissolved in the imidazolium-based ionic liquid is deposited on the plastic substrate by an ink-jet printing method, and then is cured, thereby forming the electrode 123. Herein, since the electrode 123 has a softness differently from a metal layer, it can be bent together when the substrate 120 is bent. Furthermore, since the electrode 123 has a conductivity similar to that of a metal, a signal delay does not occur.

The carbon nano tube of a gel state can be alternatively applied to a flexible LCD device or a flexible OLED device, etc.

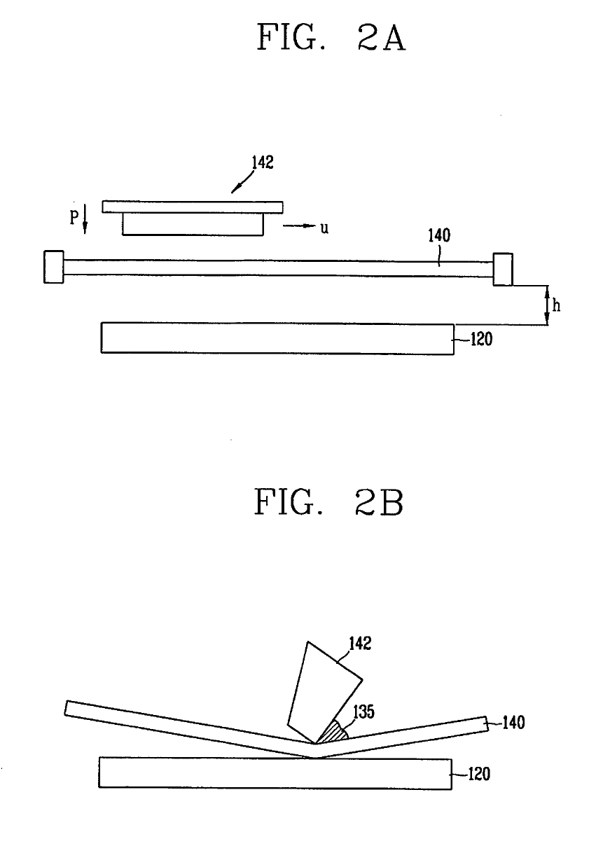

FIGS. 2A and 2B are views showing a method for forming an electrode for a flexible display device according to a second embodiment of the present invention, in which a screen printing method is used.

As shown in FIG. 2A, a screen 140 is positioned above a flexible substrate 120 such as a plastic substrate, and a carbon nano tube (not shown) of a gel state is deposited on the screen 140. The screen 140 comes in contact with a squeeze 142. The squeeze 142 moves with a constant speed (v) thus applying a certain pressure (P) to the screen 140. The carbon nano tube deposited on the screen 140 is deposited on the substrate 120 by the pressure P. An amount of the carbon nano tube deposited on the substrate 120 is determined according to a gap between the substrate 120 and the screen 140, the pressure P of the squeeze 142, and the moving speed (v) of the squeeze 142. The factors are arbitrarily set according to a size or a thickness of an electrode to be formed.

As shown in FIG. 2B, the screen 140 is positioned above the substrate 120 with a certain gap, and comes in contact with the substrate 120 by the pressure of the squeeze 142. The carbon nano tube 135 of a gel state is deposited on the screen 140, and the carbon nano tube 135 deposited on the screen 140 is deposited on the substrate 120. As the squeeze 142 moves, the carbon nano tube 135 on the screen 140 is positioned between the squeeze 142 and the screen 140, and then is deposited on the substrate 120.

In the method for forming an electrode by a screen printing method, the screen and the squeeze each having the same size as the substrate 120 are prepared, and a printing process is performed. Therefore, a desired electrode can be formed on the entire substrate by a single printing process.

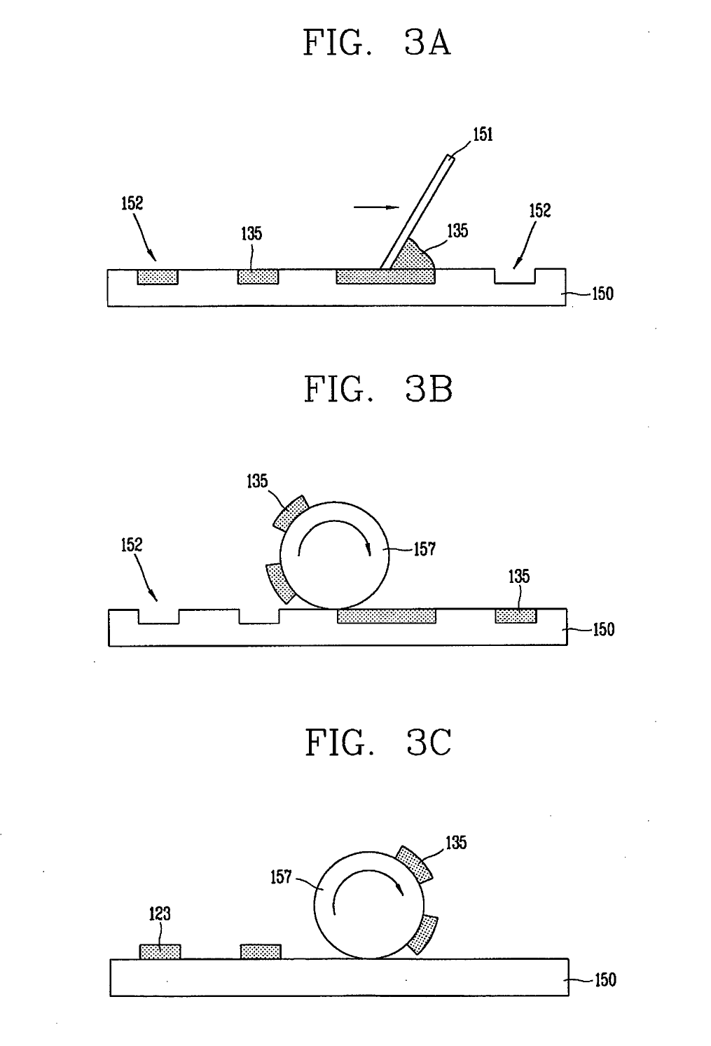

FIGS. 3A and 3B are views showing a method for forming an electrode for a flexible display device according to a third embodiment of the present invention, in which a gravure printing method is used. The gravure printing method serves to print by applying ink to a cliche and scratching redundant ink, which is variously used for publishing, packaging, cellophane, vinyl, polyethylene, etc. In the present invention, the gravure printing method was applied to form an electrode.

According to the gravure printing method, a carbon nano tube of a gel state is transferred on a substrate by using a transferring roll. Therefore, an electrode can be formed on even a large substrate by a single transferring process with using a transferring roll corresponding to a size of the substrate, which will be explained as follows.

As shown in FIG. 3A, a groove 152 is formed on a concave plate or a cliché 150 corresponding to an electrode to be formed on a flexible substrate such as a plastic substrate. Then, the carbon nano tube 135 of a gel state is contained in the groove 152. The groove 152 on the cliche 150 is minutely formed by a general photolithography method. The carbon nano tube 135 is contained in the groove 152 by depositing the carbon nano tube 135 on the cliché 150 and then moving a doctor blade 151 under a contact state to the cliche 150. Therefore, as the doctor blade 151 moves, the carbon nano tube 135 is contained in the groove 152 and the carbon nano tube 135 remaining on a surface of the cliche 150 is removed.

As shown in FIG. 3B, the carbon nano tube 135 of a gel state contained in the groove 152 of the cliché 150 comes in contact with the surface of the cliché 150 thereby to be transferred onto a surface of a transferring roll 157. The transferring roll 157 has the same width as that of the substrate on which an electrode is formed, and has a circumference having the same length as that of the substrate. Therefore, the carbon nano tube 135 contained in the groove 152 of the cliché 150 is completely transferred onto the circumferential surface of the transferring roll 157 by a single rotation. Then, as shown in FIG. 3C, the transferring roll 157 is rotated under a contact state to the surface of the substrate 120, thereby transferring the carbon nano tube 135 that has been transferred to the transferring roll 157 to the substrate 120. Then, the carbon nano tube 135 is cured for a set time at a set temperature, thereby forming an electrode 123. Herein, the electrode 123 can be formed on the entire substrate 120 by a single rotation of the transferring roll 157.

As aforementioned, in the method for forming an electrode using a gravure printing method, the cliché 150 and the transferring roll 157 can be fabricated to have a size according to the size of the substrate 120. Also, since the electrode can be formed on the substrate 120 by a single transferring, an electrode on a plastic substrate can be formed by a single process.

As aforementioned, in the present invention, the carbon nano tube is dissolved in the imidazolium-based ionic liquid as a gel state, and then is printed on the flexible substrate such as a plastic substrate, thereby forming a desired electrode pattern. The reason that the imidazolium-based ionic liquid is used is that it can dissolve the carbon nano tube by being penetrated into the carbon nano tube. Therefore, any ionic liquid can be used in the present invention only if the liquid can dissolve the carbon nano tube, and thus another solvent can be used in the present invention.

Even if the electrode is formed on the flexible substrate in the aforementioned embodiments, it can be formed on a rigid substrate such as a glass substrate. Since the carbon nano tube of a gel state dissolved in the imidazolium-based ionic liquid has an excellent conductivity and durability, it can be used as an electrode for an LCD device or an OLED device by being formed on a rigid substrate such as a glass substrate. Herein, since the electrode can be formed by a printing method, the entire fabrication process can be simplified. Also, since the minute carbon nano tube is used, an electrode having a minute line width can be formed.

As aforementioned, in the present invention, the carbon nano tube is mixed with the imidazolium-based ionic liquid thus to become a gel state having a low viscosity. Then, the carbon nano tube is deposited on the substrate by a printing method, thereby forming an electrode. Since the carbon nano tube has an excellent conductivity and softness, it can be used as a material for forming an electrode for a flexible substrate such as a plastic substrate. Furthermore, in the present invention, the carbon nano tube of a gel state is deposited on the substrate by a printing method not a photolithography method, and then is cured thus to form an electrode. Therefore, the entire fabrication process can be simplified, and the fabrication cost can be reduced.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalents of such metes and bounds are therefore intended to be embraced by the appended claims.

What is claimed is:

1. A method for forming an electrode, comprising:
forming a carbon nano tube of a gel state by mixing a carbon nano tube with an ionic liquid; and
printing the carbon nano tube of a gel state on a substrate.

2. The method of claim 1, further comprising curing the printed carbon nano tube.

3. The method of claim 1, wherein the step of printing the carbon nano tube of a gel state comprises:
supplying the carbon nano tube of a gel state to a nozzle above the substrate; and
discharging the carbon nano tube of a gel state from an opening of the nozzle, thereby depositing the carbon nano tube on the substrate.

4. The method of claim 3, wherein a thickness of the carbon nano tube deposited on the substrate is determined according to a size of the opening of the nozzle, an opened/closed state of a valve installed at the nozzle, and a moving speed of the nozzle above the substrate.

5. The method of claim 1, wherein the step of printing the carbon nano tube of a gel state comprises:
arranging a screen above the substrate;
depositing the carbon nano tube of a gel state on the screen; and
transferring the carbon nano tube of a gel state onto the screen by moving a squeeze thus applying a pressure to the screen, thereby depositing the carbon nano tube of a gel state onto the substrate.

6. The method of claim 5, wherein a thickness of the carbon nano tube deposited on the substrate is determined according to a gap between the substrate and the screen, a pressure applied to the screen by the squeeze, and a moving speed of the squeeze.

7. The method of claim 1, wherein the step of printing the carbon nano tube of a gel state comprises:
containing the carbon nano tube of a gel state in a groove of a cliche corresponding to a position of a metal pattern to be formed;
rotating a transferring roll under a contact state to the cliche, thereby transferring the carbon nano tube of a gel state contained in the groove onto a surface of the transferring roll; and
rotating the transferring roll under a contact state to the substrate, thereby re-transferring the carbon nano tube of a gel state positioned on the surface of the transferring roll to the substrate.

8. The method of claim 7, further comprising forming a groove on the cliche by a photolithography process.

9. The method of claim 1, wherein the substrate is a plastic substrate.

10. The method of claim 9, wherein the plastic substrate is formed of a material selected from a group composed of polyethylene-etherphthalate, polyethylene-naphthalate, polycarbonate, polyarylate, polyetherimide, polyethersulfone, and polyimide.

11. The method of claim 1, wherein the ionic liquid is an imidazolium-based ionic liquid.

12. The method of claim 1, wherein the substrate is a glass substrate.

13. An electrode structure, comprising:
a substrate; and
an electrode formed on the substrate with a mixture material comprising a carbon nano tube and an ionic liquid that can dissolve the carbon nano tube.

14. The electrode structure of claim 13, wherein the electrode is formed by supplying the mixture material to a nozzle above the substrate and discharging the mixture material from an opening of the nozzle, thereby depositing the mixture material on the substrate

15. The electrode structure of claim 14, wherein a thickness of the mixture material deposited on the substrate is determined according to a size of the opening of the nozzle, an opened/closed state of a valve installed at the nozzle, and a moving speed of the nozzle above the substrate.

16. The electrode structure of claim 13, wherein the electrode is formed by arranging a screen above the substrate, depositing the mixture material on the screen, and transferring the mixture material onto the screen by moving a squeeze thus applying a pressure to the screen, thereby depositing the mixture material onto the substrate.

17. The electrode structure of claim 16, wherein a thickness of the mixture material deposited on the substrate is determined according to a gap between the substrate and the screen, a pressure applied to the screen by the squeeze, and a moving speed of the squeeze.

18. The electrode structure of claim 13, wherein the electrode is formed by containing the mixture material in a groove of a cliche corresponding to a position of a metal pattern to be formed, rotating a transferring roll under a contact state to the cliche, thereby transferring the mixture material contained in the groove onto a surface of the transferring roll, and rotating the transferring roll under a contact state to the substrate, thereby re-transferring the mixture material positioned on the surface of the transferring roll to the substrate.

19. The electrode structure of claim 13, wherein the substrate is a plastic substrate.

20. The electrode structure of claim 19, wherein the plastic substrate is formed of a material selected from a group composed of polyethylene-etherphthalate, polyethylene-naphthalate, polycarbonate, polyarylate, polyetherimide, polyethersulfone, and polyimide.

21. The electrode structure of claim 13, wherein the ionic liquid is an imidazolium-based ionic liquid.

22. The electrode structure of claim 13, wherein the substrate is a glass substrate.
